(19) United States
(12) Patent Application Publication
(10) Pub. No.: US 2012/0048602 A1
(43) Pub. Date: Mar. 1, 2012

(54) METHOD OF MANUFACTURING CERAMIC SUBSTRATE FOR PROBE CARD AND CERAMIC SUBSTRATE FOR PROBE CARD

(75) Inventors: Taek Jung LEE, Hwaseong (KR); Byeung Gyu CHANG, Suwon (KR); Yun Hwi PARK, Yongin (KR)

(73) Assignee: SAMSUNG ELECTRO-MECHANICS CO., LTD.

(21) Appl. No.: 13/051,564

(22) Filed: Mar. 18, 2011

(30) Foreign Application Priority Data
Aug. 24, 2010 (KR) 10-2010-0082120

(51) Int. Cl. H05K 1/09; B23P 17/00; H05K 1/11; B29C 65/54

(52) U.S. Cl. 174/257; 156/293; 156/277; 29/527.1; 174/264

(57) ABSTRACT

There is provided a method of manufacturing a ceramic substrate for a probe card and a ceramic substrate for a probe card. The method includes preparing a ceramic substrate having a via electrode provided therein; filling a void formed between the ceramic substrate and the via electrode with a filling material including thermosetting resin; and curing the filling material. Since the void formed between the ceramic substrate and the via electrode is removed, fixation strength between the via electrode and a probe tip can be increased and a defect such as a hollow at the periphery of the via electrode can be prevented.

### CROSS-REFERENCE TO RELATED APPLICATIONS

This application claims the priority of Korean Patent Application No. 2010-0082120 filed on Aug. 24, 2010, in the Korean Intellectual Property Office, the disclosure of which is incorporated herein by reference.

### BACKGROUND OF THE INVENTION

1. Field of the Invention

The present invention relates to a method of manufacturing a ceramic substrate for a probe card and a ceramic substrate for a probe card, and more particularly, to a method of manufacturing a ceramic substrate allowing for an increase in the fixation strength of a probe tip by removing a void from the ceramic substrate and a ceramic substrate using the same.

2. Description of the Related Art

A general semiconductor test apparatus includes a tester, a performance board, a probe card, a chuck and a prober, and serves to test the electrical characteristics of chips manufactured on a wafer. Herein, the probe card receives signals generated in the tester through the performance board and transmits the signals to pads of the chips formed on the wafer, and also transmits signals outputted from the pads of the chips to the tester through the performance board.

According to the related art, a probe card includes a probe board having an opening at the center thereof and a signal line formed therein, a probe tip fixing part connected to the opening of the probe board, and a probe tip fixed to a bottom surface of the probe tip fixing part.

With a recent trend for high-integrated and compact products, the size of a chip to be tested has been reduced and the size of a pattern and a via electrode of a probe card used for testing the chip has also become compact.

In order to achieve the miniaturization of a probe card and the reliability thereof with respect to thermal shock, a ceramic substrate is being used.

A main component of a ceramic substrate is a ceramic composite including a large amount of glass, which can be subjected to low temperature co-firing.

There are a variety of methods of manufacturing a low temperature co-fired ceramic (LTCC) substrate. These methods may be divided into a shrinkage process and a non-shrinkage process according to whether a ceramic substrate, while being fired, is shrunk or not.

In the case in which a ceramic substrate is manufactured by a shrinkage process, the shrinkage of the ceramic substrate may lead to a reduction in position accuracy of an internal electrode pattern and a via electrode. For this reason, in order to increase the position accuracy, a ceramic substrate is manufactured by a non-shrinkage process.

In a ceramic substrate manufactured by a non-shrinkage process, ceramic green sheets forming individual layers are partially punched to form via holes, and the via holes are then filled with conductive paste to thereby form via electrodes. These via electrodes serve to make electrical connections between internal electrodes formed in the ceramic green sheets and external electrodes.

However, even in the case in which the ceramic substrate is manufactured by such a non-shrinkage process, the ceramic green sheets, the via electrodes, the external electrodes and the internal electrodes, formed as a ceramic stack, are formed of different materials, and accordingly, they have differences in shrinkage properties at the interfaces therebetween and in the coefficient of thermal expansion thereof during a firing process so that voids may be formed.

Such voids prevent sufficient attachment at the interfaces between the ceramic green sheets and the electrodes, so that the fixation strength of a probe tip may be reduced and a defect caused by hollows at the periphery of the via electrodes may occur. As a result, the reliability of the substrate is deteriorated.

### SUMMARY OF THE INVENTION

An aspect of the present invention provides a method of manufacturing a ceramic substrate allowing for an increase in fixation strength between a probe tip and the ceramic substrate by removing a void from the ceramic substrate. Particularly, a ceramic substrate for a probe card having high reliability is provided.

According to an aspect of the present invention, there is provided a method of manufacturing a ceramic substrate for a probe card, the method including: preparing a ceramic substrate having a via electrode provided therein; filling a void formed between the ceramic substrate and the via electrode with a filling material including a thermosetting resin; and curing the filling material.

The filling of the void with the filling material may be performed by screen printing or injection.

The method may further include polishing a surface of the ceramic substrate after the curing of the filling material.

The via electrode may be formed of a conductive material including Ag or Cu. The thermosetting resin may be a polyimide. The filling material may include Ag powder or Cu powder. The filling material may include ceramic powder. The filling material may be cured at 300° C. to 400° C.

The filling material may be used to fill a void formed on a surface of the ceramic substrate.

According to another aspect of the present invention, there is provided a ceramic substrate for a probe card, the ceramic substrate including: a ceramic substrate formed of ceramics containing glass; and a via electrode filled with a conductive material and having avoid formed between the ceramic substrate and the conductive material, the void being filled with a filling material including a thermosetting resin.

The thermosetting resin may be a polyimide. The filling material may include at least one of Ag powder and Cu powder. The filling material may include ceramic powder.

The filling material may be used to fill a void formed on a surface of the ceramic substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional viaw illustrating a probe card according to an exemplary embodiment of the present invention;

FIGS. 2A through 2C are viaws illustrating a process of removing a void from a ceramic substrate according to an exemplary embodiment of the present invention; and

FIG. 3 is a flowchart illustrating a method of removing a void from a ceramic substrate according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions may be exaggerated for clarity, and the same reference numerals will be used throughout to designate the same or like elements.

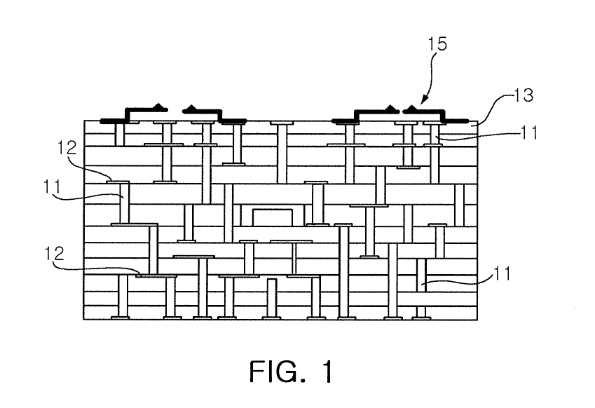

FIG. 1 is a cross-sectional viaw illustrating a probe card according to an exemplary embodiment of the present invention.

According to an exemplary embodiment of the invention, a probe card includes a probe board 13 having via electrodes formed therein and probe tips 15 connected to the probe board 13.

Signals generated in a tester of the probe card are transmitted to external electrode pads of the probe board 13 through a performance board. These signals pass through a plurality of via electrodes 11 and internal electrode patterns within the probe board 13 and are then transmitted to chip pads through the probe tips 15.

Signals outputted from the chip pads pass through the probe tips 15, the external and internal electrode patterns and the via electrodes 11, and are then transmitted to the tester through the performance board.

In this manner, a semiconductor test apparatus determines whether chips manufactured on a wafer are defective or not, through the inputting and outputting of the signals.

In recent years, as semiconductor chips have become high-integrated, semiconductor chip pads have become compact and the gaps therebetween have also been reduced. In line with this, the probe tips 15 of the probe card are manufactured by a semiconductor micro-electro-mechanical system (MEMS) process, applied to the fabrication of a microprobe.

The probe tips 15, manufactured by the MEMS process, are attached to the via electrodes 11 to which electrode pads 12 are attached. However, as the semiconductor chip pads have become compact, the via electrodes 11 formed in the probe board 13 have also become compact. In this situation, voids may be formed between the via electrodes 11 and the probe board 13 due to a difference in shrinkage rates between a conductive material filling the via electrodes 11 and a ceramic material forming the probe board 13.

The voids, formed at the periphery of the via electrodes 11, may prevent sufficient attachment between the probe tips and the electrode pads 12. According to the present invention, such voids formed around the via electrodes 11 are filled with a filling material so that fixation strength between the probe tips 15 and the electrode pads 12 may be increased and depressions around the via electrodes 11 may be avoided.

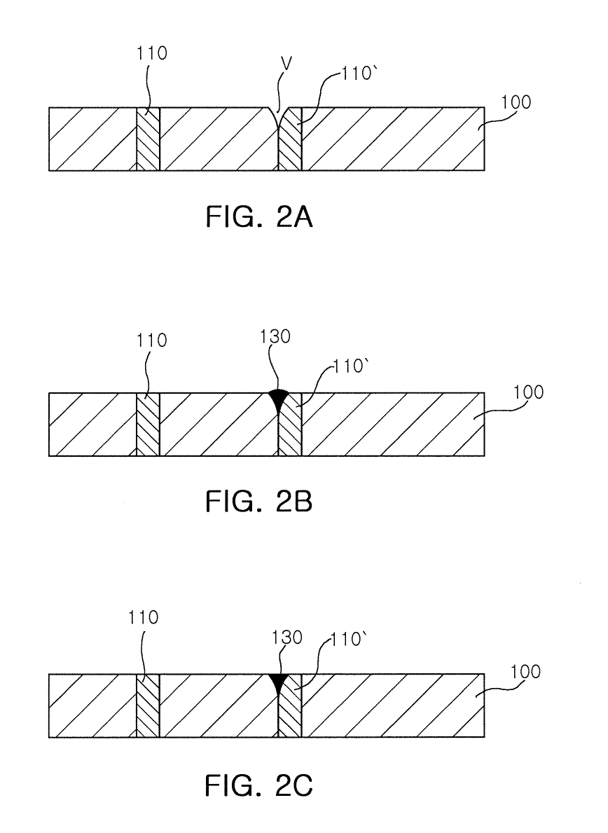

FIGS. 2A through 2C are viaws illustrating a process of removing a void from a ceramic substrate formed of a dielectric material according to an exemplary embodiment of the present invention.

With reference to FIG. 2A, a plurality of via electrodes 110 are formed in a ceramic substrate 100 for a probe card. Among the plurality of via electrodes 110, there may be a via electrode 110′ having a void V.

The plurality of via electrodes 110 may be formed by filling via holes with a conductive material.

The conductive material may be silver (Ag), copper (Cu) or the like, which has superior electrical conductivity.

According to an exemplary embodiment of the invention, the ceramic substrate 100 having the via electrodes 110 is fired and is then planarized by polishing or the like.

While the ceramic substrate 100 is subjected to a firing process, the void V may be formed due to a difference in shrinkage rates between the conductive material filling the via holes to be the via electrodes 110 and the ceramic substrate 100.

The void V is a gap or space formed at the boundary between the via electrode 110′ and the ceramic substrate 100. In the case in which the void V is formed, fixation strength between the via electrode and the probe tip may be reduced and a hollow at the periphery of the via electrode 110′ may be formed, so that a defect in the ceramic substrate 100 may occur.

With reference to FIG. 2B, the void V formed in the ceramic substrate 100 is filled with a filling material 130 in order to remove irregularities in a surface of the ceramic substrate 100.

When voids, formed on a surface of the polished substrate, are filled with the filling material 130, such a filling process may be performed by screen printing or injection, without being limited thereto.

Since the voids are filled with the filling material 130 by screen printing or direct injection, even if the voids are irregularly formed on the surface of the substrate, each of the voids may be precisely filled with the filling material 130 according to the position and size thereof.

The filling material 130 includes a thermosetting resin, which is fixed to the substrate through a curing process. The filling material 130 may be a thermosetting resin including a polyimide, which is superior in thermal resistance and chemical resistance. Since the voids of the substrate are filled with the filling material having high thermal resistance and high chemical resistance, the reliability of the substrate may be enhanced.

Meanwhile, the filling material 130 may include metallic powder or ceramic powder so that the filling density thereof may be increased.

According to an exemplary embodiment of the invention, the filling material 130 may include Ag powder or Cu powder. In the case in which the void V is filled with the filling material 130 including a conductive material, which forms the via electrode 110′, such as Ag powder or Cu powder, the filling material 130 may be attached to the via electrode 110′ to thereby form a portion of the via electrode 110′.

According to another exemplary embodiment of the invention, the filling material 130 may include ceramic powder. In the case in which the void V is filled with the filling material 130 including ceramic powder, which forms the ceramic substrate 100, the filling material 130 may serve to form a portion of the ceramic substrate.

The void formed on the surface of the ceramic substrate 100 as well as the void V formed at the periphery of the via electrode 110′ is filled with the filling material 130 such that the filling material 130 may serve to smooth the surface of the ceramic substrate 100.

After the filling of the voids with the filling material 130, the filling material 130 may be cured. A thermosetting resin including a polyimide is cured in an oven at 300° C. to 400° C. for approximately one hour.

Since the filling material 130, when the voids are being filled therewith, is in a liquid state containing powder, the filling material 130 may be cured at 300° C. to 400° C. Since the filling material 130 includes powder, it can be cured at a low temperature, and since the filling material 130 is cured at a low temperature, this may minimize the influence of heat treatment on the ceramic substrate subjected thereto.

After the curing of the filling material 130, the surface of the ceramic substrate 100 may be polished.

According to an exemplary embodiment of the invention, in order to fill the irregularly formed voids, each of the voids is filled with the filling material 130 by screen printing or injection according to the position and size thereof. In the case in which the filling material 130 protrudes from the surface of the ceramic substrate 100, this may cause irregularities in the ceramic substrate 100 so that the fixation strength in the attachment of the probe tip 15 may be reduced.

Therefore, in order to planarize the ceramic substrate 100, the surface of the ceramic substrate 100 may be polished. This polishing process allows the surface of the ceramic substrate 100 to be planarized.

After the curing process is completed, the probe tip 15 is attached to the via electrode by the MEMS process, whereby a probe card is completely formed.

A probe card manufactured according to an exemplary embodiment of the invention allows for an increase in fixation strength between a via electrode and a probe tip and prevents the formation of any void at the periphery of the via electrode so that a hollow at the periphery of the via electrode and a defective substrate caused thereby may be avoided.

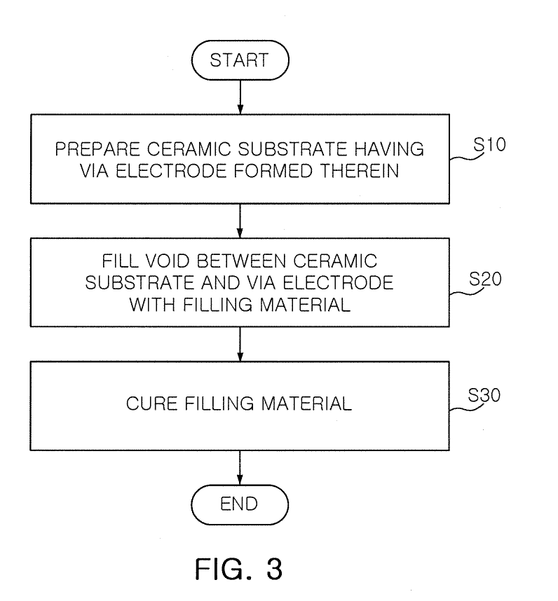

FIG. 3 is a flowchart illustrating a method of removing a void from a ceramic substrate according to an exemplary embodiment of the present invention.

According to an exemplary embodiment of the invention, a ceramic substrate having a plurality of via electrodes formed therein is prepared by filling a plurality of via holes with a conductive material and performing a firing process in operation S10. The conductive material filling the via holes may include a material having superior electrical conductivity, such as Ag or Cu.

During the firing process, when voids are formed between the via electrodes and the ceramic substrate, the voids are filled with a filling material in operation S20.

Each of the voids may be filled with an appropriate amount of filling material by screen printing or injection according to the position and size thereof.

The filling material may be a thermosetting resin including a polyimide. When the filling material includes Ag powder or Cu powder mixed therewith and the voids are filled therewith, the filling material may serve as an auxiliary material of the via electrodes.

Also, when the filling material includes ceramic powder mixed therewith and the voids are filled therewith, the filling material may serve to planarize the surface of the ceramic substrate by filling the voids formed on the surface of the ceramic substrate.

Thereafter, the voids filled with the filling material are cured in operation S30. Then, the surface of the ceramic substrate is further planarized by a polishing process or the like, and a probe tip is attached thereto by an MEMS process, and thus a probe card is formed.

According to an exemplary embodiment of the invention, since a void is filled with a filling material, a defect of a substrate caused by such a void at the periphery of a via electrode may be avoided. Also, a surface area for an MEMS probe tip is increased to thereby raise fixation strength between the probe tip and the via electrode.

Also, since the filling material includes a material having high attachment force and high chemical resistance such as a polyimide, the substrate may have improved reliability.

Furthermore, since the filling material serves as an auxiliary material of the via electrode, this leads to a reduction in the electrical resistance of a pattern connected to the via electrode. For this reason, when a multilayer electronic component for a probe card is manufactured, an advantageous design in terms of impedance matching may be achieved.

As set forth above, in a ceramic substrate for a probe card and a manufacturing method thereof according to exemplary embodiments of the invention, fixation strength between a probe tip and a ceramic substrate is increased by removing a void from the ceramic substrate and the ceramic substrate is planarized, whereby the ceramic substrate can achieve improved reliability.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a ceramic substrate for a probe card, the method comprising:
preparing a ceramic substrate having a via electrode provided therein;
filling a void formed between the ceramic substrate and the via electrode with a filling material including a thermosetting resin; and
curing the filling material.

2. The method of claim 1, wherein the filling of the void with the filling material is performed by screen printing or injection.

3. The method of claim 1, further comprising polishing a surface of the ceramic substrate after the curing of the filling material.

4. The method of claim 1, wherein the via electrode is formed of a conductive material including Ag or Cu.

5. The method of claim 1, wherein the thermosetting resin is a polyimide.

6. The method of claim 1, wherein the filling material includes Ag powder or Cu powder.

7. The method of claim 1, wherein the filling material includes ceramic powder.

8. The method of claim 1, wherein the filling material is cured at 300° C. to 400° C.

9. The method of claim 1, wherein the filling material is used to fill a void formed on a surface of the ceramic substrate.

10. A ceramic substrate for a probe card, the ceramic substrate comprising:
a ceramic substrate formed of ceramics containing glass; and
a via electrode filled with a conductive material and having a void formed between the ceramic substrate and the conductive material, the void being filled with a filling material including a thermosetting resin.

11. The ceramic substrate of claim 10, wherein the thermosetting resin is a polyimide.

12. The ceramic substrate of claim 10, wherein the filling material includes at least one of Ag powder and Cu powder.

13. The ceramic substrate of claim 10, wherein the filling material includes ceramic powder.

14. The ceramic substrate of claim 10, wherein the filling material is used to fill a void formed on a surface of the ceramic substrate.
